(19) United States
(12) Patent Application Publication
(10) Pub. No.: US 2009/0059691 A1
(43) Pub. Date: Mar. 5, 2009

(54) SEMICONDUCTOR INTEGRATED CIRCUIT AND MULTI TEST METHOD THEREOF

(75) Inventors: Shin Ho Chu, Ichon (KR); Jong Won Lee, Ichon (KR)

Correspondence Address: BAKER & MCKENZIE LLP;PATENT DEPARTMENT, 2001 ROSS AVENUE, SUITE 2300, DALLAS, TX, 75201, US

(73) Assignee: HYNIX SEMICONDUCTOR, INC., Ichon (KR)

(21) Appl. No.: 12/169,594

(22) Filed: Jul. 8, 2008

(30) Foreign Application Priority Data
Sep. 4, 2007 (KR) 10-2007-0089489

(51) Int. Cl. G11C 7/00; G11C 8/00

(52) U.S. Cl. 365/191; 365/230.06; 365/201

(57) ABSTRACT

A semiconductor integrated circuit includes a multi-mode control signal generating section that enables one of up and down mat input/output switch control signals for controlling input/output switches in up and down mats according to up/down information addresses during a read operation mode, a multi-mode decoding section that simultaneously activates multi mat selection signals corresponding to one of the up mats and one of the down mats according to row addresses in an active operation mode, and a mat control section that receives the up and down mat input/output switch control signals and the multi mat selection signals and enables word lines and input/output switches in the mats corresponding to the signals.

### CROSS REFERENCE TO RELATED APPLICATION

The present application claims priority under 35 U.S.C. 119(a) to Korean application number 10-2007-0089489, filed in the Korean Intellectual Property Office on Sep. 4, 2007, which is incorporated by reference in its entirety as if set forth in full.

### BACKGROUND

1. Technical Field

The embodiments described herein relate to a semiconductor integrated circuit, and more particularly, to a semiconductor integrated circuit and a multi test method thereof capable of reducing a test time.

2. Related Art

FIG. 1 is a block diagram illustrating a conventional semiconductor integrated circuit 1. Referring to FIG. 1, the semiconductor integrated circuit 1 includes a plurality of mats 10, a plurality of bit line sense amplifier array blocks 20, a plurality of input/output switching units 30, a plurality of mat control units 90, a row decoder 50, and an input/output sense amplifier 40.

Each mat 10 includes a plurality of cells, and data loaded on the cells is transmitted to a pair of bit lines when a word line is activated. The bit line sense amplifier array block 20 senses and amplifies the data loaded on each pair of bit lines.

The plurality of input/output switching units 30 receive a plurality of input/output switch signals ‘iosw<0,1, . . . >’, and transmit data loaded on a plurality of segment input/output lines SIO<0,1, . . . > to local input/output lines LIO<n>.

The row decoder 50 receives row address signals ‘Xadd<0:P>’ according to an active signal ‘Act-pre<N>’, and decodes the row addresses to generate decoded signals ‘msb<0:M−1>’ and an input/output switch enable signal ‘iosw_en’ for activating the plurality of input/output switch signals ‘iosw<0,1,..>’.

The first to (M+2)-th mat control units 90 receive the input/output switch enable signal ‘iosw_en’ and the decoded signals ‘msb<0:M−1>’ and output a sense amplifier enable signal for activating the sense amplifier, word line enable signals for activating word lines, and the input/output switch signals ‘iosw<0,1, . . . >’.

The input/output sense amplifier 40 transmits data loaded on the local input/output line LIO<n> to a global input/output line GIO. Then, the data loaded on the global input/output line GIO is transmitted to a data pad DQ PAD, and then transmitted to an external semiconductor integrated circuit controller (for example, a DRAM controller).

In the semiconductor integrated circuit having the above-mentioned structure, during a burn-in test, the word lines and the sense amplifiers in the mats are sequentially driven in response to the row address signals ‘Xadd<0:P>’ input from the outside, and write and read operations are verified. As shown in FIG. 1, the segment input/output lines SIO<1:M+1> in each of the mats are connected to one local input/output line LIO<n> by the input/output switching units 30. Data loaded on the segment input/output lines SIO<1:M+1> is transmitted to the local input/output line LIO<n> by the switching unit 30 in an enabled state among the input/output switching units 30.

That is, in the semiconductor integrated circuit shown in FIG. 1, during a read operation, only one input/output switching unit 30 is enabled, and data loaded on the cell of the corresponding mat is transmitted to the local input/output line LIO<n>.

FIG. 2 is a circuit diagram schematically illustrating a data read path in the semiconductor integrated circuit 1 shown in FIG. 1. Referring to FIG. 2, it can be seen that during a read operation within circuit 1, data passes through a bit line sense amplifier 21 of the bit line sense amplifier array block 20, a column selection transistor 60, a switching element 31 of the input/output switching unit 30, a precharging unit 70, the input/output sense amplifier 40, and an output device 80.

The read operation of the semiconductor integrated circuit 1 is performed as follows: First, an active instruction signal activates one of a plurality of word lines in the mats, and data from the cells connected to the word line is loaded on a pair of bit lines BL and BLB connected to the word line by charge sharing. Then, the bit line sense amplifier 21 senses and amplifies the data loaded on the pair of bit lines BL and BLB. Thereafter, data that is loaded on the bit line BL corresponding to a column address among a plurality of bit lines connected to the word line is output by a read instruction signal. That is, when a column selection signal ‘yi’ is enabled, the column selection transistor 60 is turned on and the data loaded on the pair of bit lines BL and BLB is transmitted to a pair of segment input/output lines SIO and SIOB. Then, the data loaded on the pair of segment input/output lines SIO and SIOB is transmitted to a pair of local input/output lines LIO and LIOB, and the data loaded on the pair of local input/output lines LIO and LIOB is input to the input/output sense amplifier 40. The input/output sense amplifier 40 amplifies the input data and outputs the amplified data to the data pad DQ PAD.

FIG. 3 is a timing diagram illustrating the operation of the semiconductor integrated circuit 1 shown in FIGS. 1 and 2. In an active mode “Act”, an active precharge signal ‘Act_pre’ is enabled, and an input/output switch enable signal ‘iosw_en’ is enabled to operate the input/output switching unit 31. In addition, a mat selection signal ‘msb<0>’ is enabled at a low level, and the word line in the mat is enabled. When the word line is enabled, data loaded on the cell is amplified by the bit line sense amplifier 21, and the voltage levels of the pair of bit lines BL and BLB reach a core voltage level and a ground voltage level, respectively.

Then, in a read operation mode “Read”, when the column selection signal ‘yi’ is enabled, the data loaded on the pair of bit lines BL and BLB is loaded on the pair of segment input/output lines SIO and SIOB (in this case, the voltage of the bit line is reduced by a voltage Delta V).

Then, in a precharge mode “Pre”, the pair of bit lines BL and BLB are precharged, and the pair of segment input/output lines SIO and SIOB are also precharged.

However, as described above, since the segment input/output lines SIO<1:M+1> in each of the mats are connected to one local input/output line LIO<n>, a burn-in test needs to be individually performed for each mat, which results in an increase in the test time. Further, during the test, it is possible to enable a plurality of mats and a plurality of word lines at the same time, but it is difficult to enable a plurality of word lines and a plurality of column lines at the same time.

That is, in a conventional test is required to independently enable row addresses and column addresses in order to test cells in the banks of the semiconductor integrated circuit. As a result, an excessively long test time is required during mass production of semiconductor integrated circuits, which results in an increase in manufacturing costs.

### SUMMARY

A semiconductor integrated circuit capable of reducing a test time is described herein. A semiconductor integrated circuit capable of reducing a test time by simultaneously activating a plurality of mats during a test related to read and write operation as well as a test related to an active operation, at the time of a burn-in test is also described herein.

According to an aspect, a semiconductor integrated circuit includes a multi-mode control signal generating section configured to enable one of up and down mat input/output switch control signals for controlling input/output switches in up and down mats according to up/down information addresses in a read operation mode, a multi-mode decoding section configured to simultaneously activate multi mat selection signals corresponding to one of the up mats and one of the down mats according to row addresses in an active operation mode, and a mat control section configured to receive the up and down mat input/output switch control signals and the multi mat selection signals and enables word lines and input/output switches corresponding to the signals.

According to another aspect, there is provided a multi test method of a semiconductor integrated circuit. The method includes activating one of up mats and one of down mats to perform an active operation when a multi test is performed, activating an up mat input/output switch control signal and deactivating a down mat input/output switch control signal according to up/down information addresses, reading data from one of the up mats according to the activated up mat input/output switch control signal, deactivating the up mat input/output switch control signal and activating the down mat input/output switch control signal according to the up/down information addresses, and reading data from one of the down mats according to the activated down mat input/output switch control signal.

These and other features, aspects, and embodiments are described below in the section entitled “Detailed Description.”

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a block diagram illustrating a conventional semiconductor integrated circuit.

FIG. 2 is a detailed circuit diagram illustrating components of the semiconductor integrated circuit shown in FIG. 1 including data lines.

FIG. 3 is a timing diagram illustrating the operation of the semiconductor integrated circuit shown in FIGS. 1 and 2.

FIG. 4 is a block diagram illustrating a semiconductor integrated circuit according to an embodiment.

FIG. 5 is a detailed circuit diagram illustrating a multi read signal generating unit that can be included in the circuit shown in FIG. 4.

FIG. 6 is a detailed circuit diagram illustrating an input/output switch control signal generating unit that can be included in the circuit shown in FIG. 4.

FIG. 7 is a detailed circuit diagram illustrating a mat selection decoding unit that can be included in the circuit shown in FIG. 4.

FIG. 8 is a timing diagram illustrating the operation of the semiconductor integrated circuit shown in FIGS. 4 to 7.

FIG. 9 is a block diagram illustrating an up mat control unit and a down mat control unit that can be included in the circuit shown in FIG. 4.

FIG. 10 is a detailed circuit diagram illustrating a third up mat control unit and a third down mat control unit that can be included in the unit shown in FIG. 9.

FIG. 11 is a block diagram illustrating a semiconductor integrated circuit according to another embodiment.

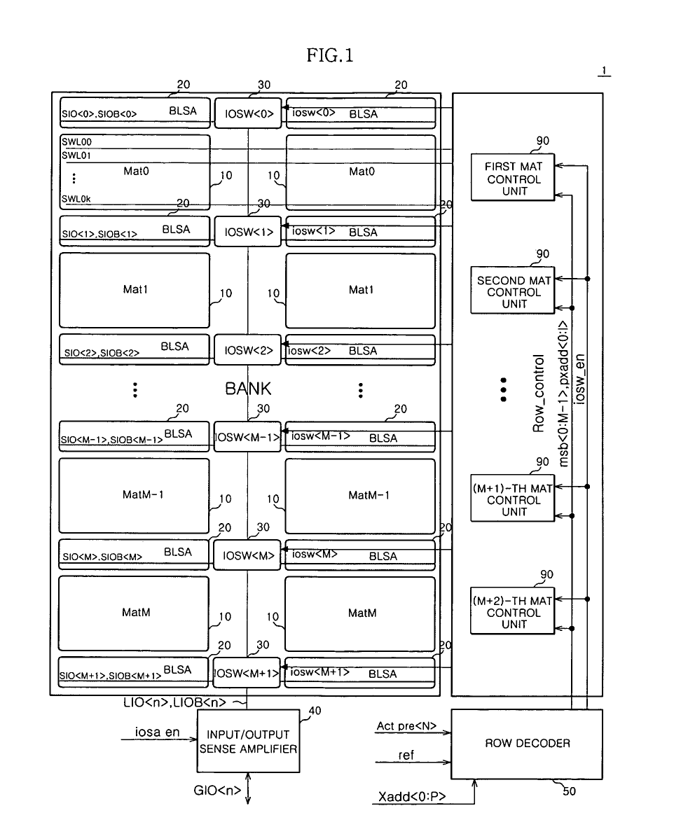

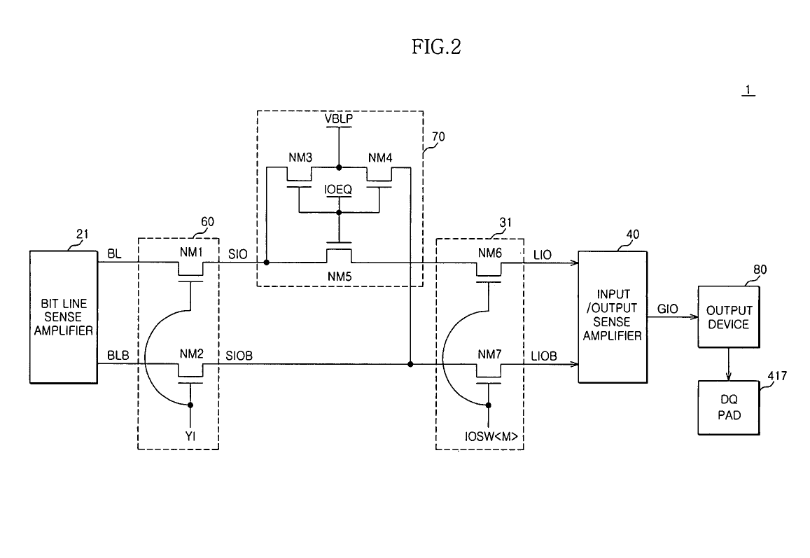

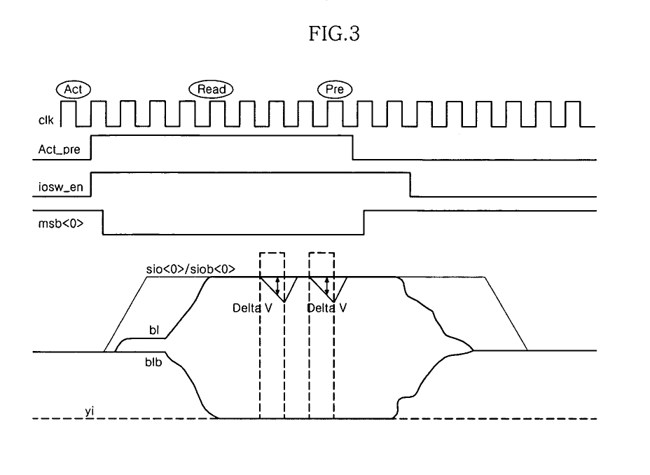

### DETAILED DESCRIPTION

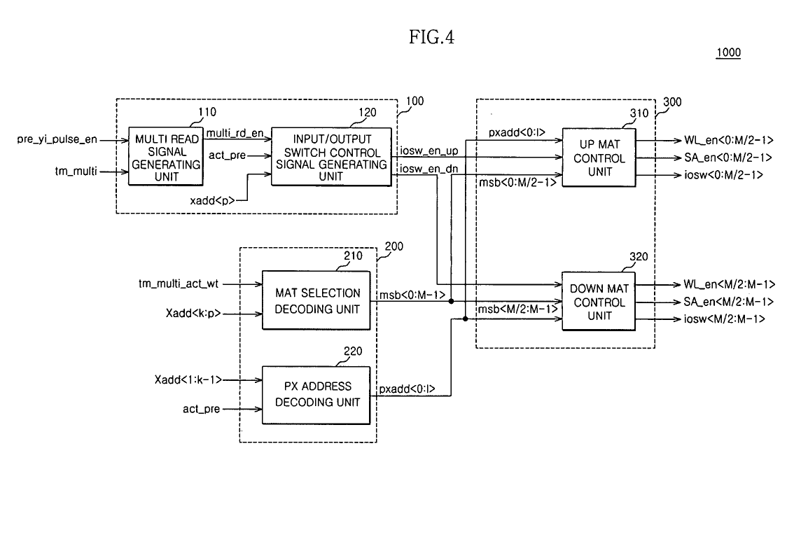

FIG. 4 is diagram illustrating a semiconductor circuit 1000 according to one embodiment. Referring to FIG. 4, the semiconductor integrated circuit 1000 can include a multi-mode control signal generating section 100, a multi-mode decoding section 200, and a mat control section 300.

The multi-mode control signal generating section 100 can be configured to generate and enable an up mat input/output switch control signal ‘iosw_en_up’ that controls input/output switches in up mats, or a down mat input/output switch control signal ‘iosw_en_dn’ that controls input/output switches in down mats, according to an up/down information address signal ‘Xadd<p>’ and during a read operation of a multi test mode. The multi test mode is an operation mode in which a plurality of mats are simultaneously activated to perform a test.

The up/down information address signal ‘Xadd<p>’ is a signal that can be used to discriminate the up mats from the down mats. The up/down information address signal ‘Xadd<p>’ can be input according to a read instruction in order to discriminate two continuous read operations. An address that is not used during a column operation may be used as the up/down information address signal ‘Xadd<p>’. Alternatively, the up/down information address signal ‘Xadd<p>’ may be input through a DM (data mask) pin (not shown).

Depending on the embodiment, when the up/down information address signal ‘Xadd<p>’ is at, e.g., a low level, it may be used as a signal for activating the up mat. When the up/down information address signal ‘Xadd<p>’ is, e.g., at a high level, it may be used as a signal for activating the down mat.

The up mats can be provided in the upper half of one bank, and the down mats can be provided in the lower half of the bank. In this case, the up mat and the down mat that are disposed at corresponding positions can receive the same address except for the up/down information address signal ‘Xadd<p>’.

The multi-mode control signal generating section 100 can be implemented by a logic circuit that enables one of two signals according to the up/down information address signal ‘Xadd<p>’ during the read operation. As mentioned, one of the two signals can serve as the up mat input/output switch control signal ‘iosw_en_up’ that controls the input/output switches in the up mats, and the other signal serves as the down mat input/output switch control signal ‘iosw_en_dn’ that controls the input/output switches in the down mats.

Specifically, the multi-mode control signal generating section 100 can include a multi read signal generating unit 110 and an input/output switch control signal generating unit 120. The multi read signal generating unit 110 can receive a multi test mode signal ‘tm_multi’ and a column pulse enable signal ‘pre_yi_pulse_en’, and output a multi read signal ‘multi_rd_en’. The multi read signal generating unit 110 can, e.g., be configured to output a high-level multi read signal ‘multi_rd_en’, when the multi test mode signal ‘tm-multi’ is enabled at a high level in the multi test mode and the column pulse enable signal ‘pre_yi_pulse_en’ is also at a high level.

The multi test mode signal ‘tm_multi’ can be activated during the multi test mode, and the column pulse enable signal ‘pre_yi_pulse_en’ can be for generating the column selection signal ‘yi’. For example, when the column pulse enable signal ‘pre_yi_pulse_en’ is enabled, the column selection signal ‘yi’ can be enabled after a predetermined time has elapsed.

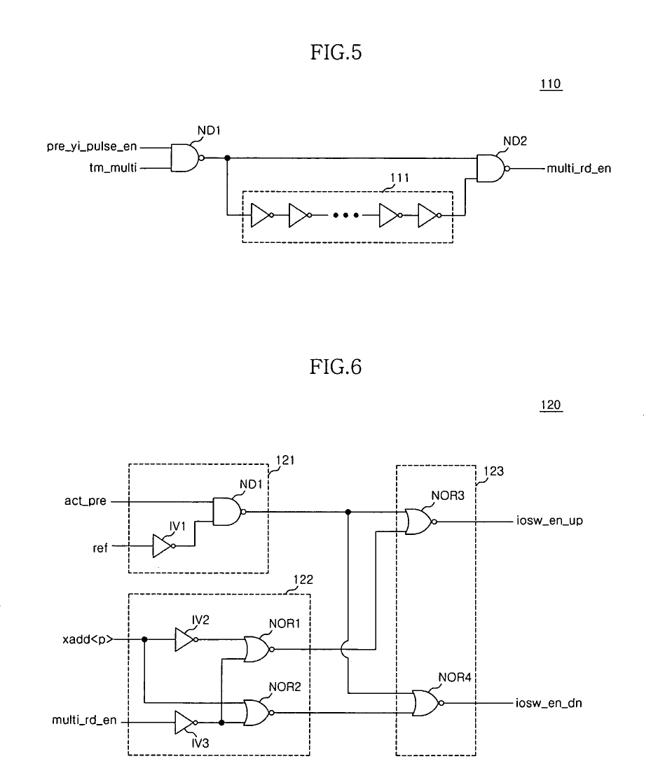

As shown in FIG. 5, the multi read signal generating unit 110 can include a first NAND gate ND1, a second NAND gate ND2, and a delay unit 111. The first NAND gate ND1 can receive the column pulse enable signal ‘pre_yi_pulse_en’ and the multi test mode signal ‘tm_multi’ and perform a NAND operation thereon. The delay unit 111 can be configured to delay the output of the first NAND gate ND1. The delay unit 111 can, e.g., be composed of a plurality of inverters connected in series with each other. The delay unit 111 can cause the pulse width of the multi read signal ‘multi_rd_en’ to be larger than that of the column pulse enable signal ‘pre_yi_pulse_en’. The second NAND gate ND2 can be configured to receive the output of the first NAND gate ND1 and the output of the delay unit 111 and perform a NAND operation on the received signals.

Accordingly, the multi read signal generating unit 110 can be configured to output a high-level multi read signal ‘multi_rd_en’, when the multi test mode signal ‘tm_multi’ is at a high level and the column pulse enable signal ‘pre_yi_pulse_en’ is also at a high level. Further, the multi read signal generating unit 110 can be configured to output a low-level multi read signal ‘multi_rd_en’, regardless of the level of the column pulse enable signal ‘pre_yi_pulse_en’, when the multi test mode signal ‘tm_multi’ is at a low level.

Referring again to FIG. 4, the input/output switch control signal generating unit 120 can receive an active signal ‘act_pre’, a refresh signal ‘ref’, the up/down information address signal ‘Xadd<p>’, and the multi read signal ‘multi_rd_en’, and output the up mat input/output switch control signal ‘iosw_en_up’ and the down mat input/output switch control signal ‘iosw_en_dn’.

Referring to FIG. 6, the input/output switch control signal generating unit 120 can include an active driver 121, a multi test controller 122, and an output unit 123. The active driver 121 can be configured to receive the active signal ‘act_pre’ and the refresh signal ‘ref’. The active driver 121 can include a first inverter IV1 and a first NAND gate ND1. The first inverter IV1 can be configured to invert the refresh signal ‘ref’. The first NAND gate ND1 can be configured to receive the output of the first inverter IV1 and the active signal ‘act_pre’ and performs a NAND operation on the received signals.

The multi test controller 122 can be configured to receive the up/down information address signal ‘Xadd<p>’ and the multi read signal ‘multi_rd_en’. The multi test controller 122 can include a second inverter IV2, a third inverter IV3, a first NOR gate NOR1, and a second NOR gate NOR2. The second inverter IV2 can receive and invert the up/down information address signal ‘Xadd<p>’. The third inverter IV3 can receive and invert the multi read signal ‘multi_rd_en’. The first NOR gate NOR1 can receive the output of the second inverter IV2 and the output of the third inverter IV3 and perform a NOR operation on the received signals. The second NOR gate NOR2 can receive the up/down information address signal ‘Xadd<p>’ and the output of the third inverter IV3 and perform a NOR operation on the received signals.

The output unit 123 can receive the output of the active driver 121 and the output of the multi test controller 122, and output the up mat input/output switch control signal ‘iosw_en_up’ and the down mat input/output switch control signal ‘iosw_en_dn’.

The output unit 123 can include a third NOR gate NOR3 and a fourth NOR gate NOR4. The third NOR gate NOR3 can receive the output of the first NAND gate ND1 of the active driver 121 and the output of the first NOR gate NOR1 of the multi test controller 122, and output the up mat input/output switch control signal ‘iosw_en_up’. The fourth NOR gate NOR4 can receive the output of the first NAND gate ND1 of the active driver 121 and the output of the second NOR gate NOR2 of the multi test control unit 122, and output the down mat input/output switch control signal ‘iosw_en_dn’.

The operation of the input/output switch control signal generating unit 120 shown in FIG. 6 will be described below.

When the multi read signal ‘multi_rd_en’ is at a low level, the third inverter IV3 outputs a high-level signal. Therefore, the first NOR gate NOR1 and the second NOR gate NOR2 output low-level signals, regardless of the up/down information address signal ‘Xadd<p>’. Meanwhile, when the active signal ‘act_pre’ is at a high level and the refresh signal ‘ref’ is at a low level, the first NAND gate ND1 outputs a low-level signal. Therefore, since low-level signals are input to the third NOR gate NOR3 and the fourth NOR gate NOR4, the third NOR gate NOR3 and the fourth NOR gate NOR4 output high-level signals. That is, both the up mat input/output switch control signal ‘iosw_en_up’ and the down mat input/output switch control signal ‘iosw_en_dn’ become high level signals.

In addition, in a refresh mode, when the refresh signal ‘ref’ is at a high level, the first NAND gate ND1 outputs a high-level signal, and the third NOR gate NOR3 and the fourth NOR gate NOR4 output low-level signals. When the multi read signal ‘multi_rd_en’ is at a low level, in an active operation mode, both the up mat input/output switch control signal ‘iosw_en_up’ and the down mat input/output switch control signal ‘iosw_en_dn’ become high level signals.

When the multi read signal ‘multi_rd_en’ is at a high level, the third inverter IV3 outputs a low level signal, and the first NOR gate NOR1 and the second NOR gate NOR2 output different values according to the up/down information address signal ‘Xadd<p>’. That is, when the up/down information address signal ‘Xadd<p>’ is at a high level, the first NOR gate NOR1 outputs a high-level signal, and the second NOR gate NOR2 outputs a low-level signal.

Therefore, the third NOR gate NOR3 receiving the output of the first NOR gate NOR1 outputs a low-level up mat input/output switch control signal ‘iosw_en_up’, regardless of the active signal ‘act_pre’. The fourth NOR gate NOR4 receiving the output of the second NOR gate NOR2 outputs a high-level signal when the active signal ‘act_pre’ is enabled, and outputs a low-level down mat input/output switch control signal ‘iosw_en_dn’ when the active signal ‘act_pre’ is disabled.

When the up/down information address signal ‘Xadd<p>’ is at a low level, the first NOR gate NOR1 outputs a low-level signal, and the second NOR gate NOR2 outputs a high-level signal. Therefore, the fourth NOR gate NOR4 outputs a low-level signal, regardless of the level of the active signal ‘act_pre’, and the output of the third NOR gate NOR3 depends on the active signal ‘act_pre’.

Therefore, when the multi read signal ‘multi_rd_en’ is enabled, one of the outputs of the third NOR gate NOR3 and the fourth NOR gate NOR4 is enabled according to the up/down information address signal ‘Xadd<p>’. That is, the up mat input/output switch control signal ‘iosw_en_up’ or the down mat input/output switch control signal ‘iosw_en_down’ is enabled.

Referring again to FIG. 4, the multi-mode decoding section 200 can be configured to activate multi mat selection signals corresponding to one of the up mats and one of the down mats according to a row address during the active operation of the multi test mode. The multi-mode decoding section 200 can simultaneously activate word lines in one of the up mats and word lines in one of the down mats, that is, word lines in a plurality of mats, in the active operation mode.

Specifically, the multi-mode decoding section 200 can include a mat selection decoding unit 210 and a PX address decoding unit 220. The mat selection decoding unit 210 can be configured to receive mat information address signals ‘Xadd<k:P>’ according to the multi test mode active write signal ‘tm_multi_act_wt’, decode the received address signals, and output multi mat selection signals ‘msb<0:M−1>’.

The multi test mode active write signal ‘tm_multi_act_wt’ can be enabled during the active mode and a write operation mode. Therefore, when the multi test mode active write signal ‘tm_multi_act_wt’ is enabled, the multi mat selection signals ‘msb<0:M−1>’ can be enabled in each of one of the up mats and one of the down mats, and the word lines in one of the up mats and one of the down mats can be simultaneously enabled. The multi mat selection signals ‘msb<0:M−1>’ can include information for selecting the corresponding mat according to an input row address.

The PX address decoding unit 220 can be configured to receive the active signal ‘act_pre’ and row address signals ‘Xadd<1:k−1>’, decode the row address signals ‘Xadd<1:k−1>’, and output a PX address signal ‘pxadd<0:l>’. The corresponding word line and the corresponding sense amplifier can be enabled in response to the PX address signal ‘pxadd<0:l>’. The PX address signal ‘pxadd<0:l>’ can indicate information related to the word lines in each mat and can activate the word line.

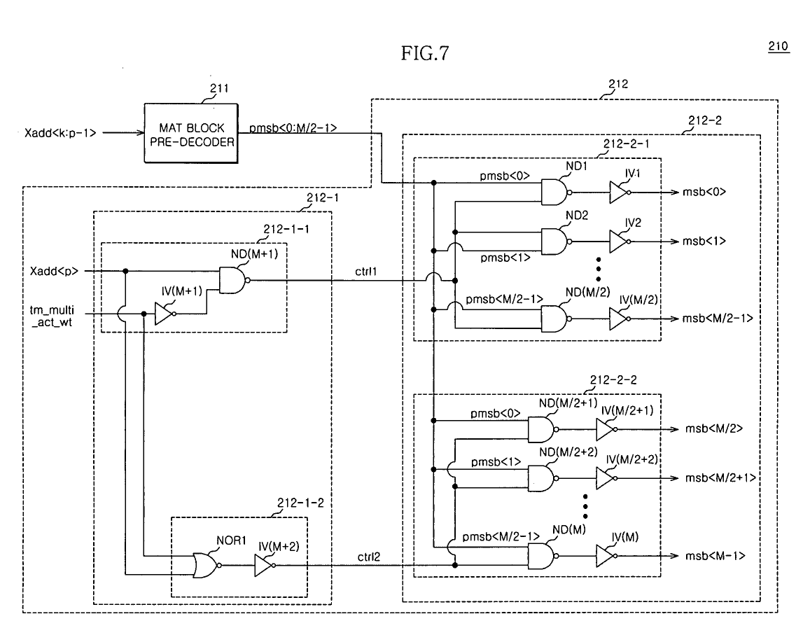

Referring to FIG. 7, the mat selection decoding unit 210 can include a mat block pre-decoder 211 and a main decoder 212. The mat block pre-decoder 211 can be configured to pre-decode the row address signals ‘Xadd<k: p−1>’ and output pre-decoded signals ‘pmsb<0:M/2−1>’. The main decoder 212 can receive and decode the pre-decoded signals ‘pmsb<0:M/2−1>’ according to the multi test active write signal ‘tm_multi_act_wt’ and the up/down information address signal ‘Xadd<p>’.

The main decoder 212 can include a mat control unit 212-1 and a decoder 212-2. The mat control unit 212-1 can receive the multi test mode active write signal ‘tm_multi_act_wt’ and the up/down information address signal ‘Xadd<p>’, and output an up mat control signal ‘ctrl1’ and a down mat control signal ‘ctrl2’. The decoder 212-2 can receive the pre-decoded signals ‘pmsb<0:M/2−1>’, the up mat control signal ‘ctrl1’, and the down mat control signal ‘ctrl2’, and output decoded signals ‘msb<0:M−1>’.

The mat control unit 212-1 can include an up mat controller 212-1-1 and a down mat controller 212-1-2. The up mat controller 212-1-1 can be configured to output the up mat control signal ‘ctrl1’ that is enabled when the up mat is selected during the multi test mode. The down mat controller 212-1-2 can be configured to output the down mat control signal ‘ctrl2’ that is enabled when the down mat is selected during the multi test mode.

The up mat controller 212-1-1 can include an (M+1)-th inverter IV(M+1) and an (M+1)-th NAND gate ND(M+1). The (M+1)-th inverter IV(M+1) can be configured to receive and invert the multi test mode active write signal ‘tm_multi_act_wt’. The (M+1)-th NAND gate ND(M+1) can receive the output of the (M+1)-th inverter IV(M+1) and the up/down information address signal ‘Xadd<p>’, and perform a NAND operation on the received signals to generate the up mat control signal ‘ctrl1’.

The down mat controller 212-1-2 can include a NOR gate NOR1 and an inverter IV(M+2). The NOR gate NOR1 can receive the multi test active write signal ‘tm_multi_act_wt’ and the up/down information address signal ‘Xadd<p>’, and can perform a NOR operation on the received signals to generate the down mat control signal ‘ctrl2’.

The decoder 212-2 can include an up mat decoder 212-2-1 and a down mat decoder 212-2-2. The up mat decoder 212-2-1 can be configured to receive the up mat control signal ‘ctrl1’ and the pre-decoded signals ‘pmsb<0:M/2−1>’ and generate decoded signals ‘msb<0:M/2−1>’. The down mat decoder 212-2-2 can be configured to receive the down mat control signal ‘ctrl2’ and the pre-decoded signals ‘pmsb<0:M/2−1>’ and generate decoded signals ‘msb<M/2:M−1>’.

When the up mat control signal ‘ctrl1’ is enabled, the up mat decoder 212-2-1 can output the pre-decoded signals ‘pmsb<0:M/2−1>’ as the decoded signals ‘msb<0:M/2−1>’. When the down mat control signal ‘ctrl2’ is enabled, the down mat decoder 212-2-2 can output the pre-decoded signals ‘pmsb<0:M/2−1>’ as the decoded signals ‘msb<M/2:M−1>’.

The up mat decoder 212-2-1 can include a plurality of NAND gates ND1 to ND(M/2) and a plurality of inverters IV1 to IV(M/2). The plurality of NAND gates ND1 to ND(M/2) can receive pre-decoded signals ‘pmsb<0:M/2−1>’ of the up mat among the pre-decoded signals ‘pmsb<0:M/2−1>’ and the up mat control signal ‘ctrl1’, and perform a NAND operation on the received signals. The plurality of inverters IV1 to IV(M/2) can receive and invert the outputs of the plurality of NAND gates ND1 to ND(M/2) and output the decoded signals ‘msb<0:M/2−1>’.

The down mat decoder 212-2-2 can include a plurality of NAND gates ND(M/2)+1 to ND(M) and a plurality of inverters IV(M/2)+1 to IV(M). The plurality of NAND gates ND(M/2)+1 to ND(M) can receive pre-decoded signals ‘pmsb<0:M/2−1>’ of the down mat among the pre-decoded signals ‘pmsb<0:M/2−1>’ and the down mat control signal ‘ctrl2’, and can perform a NAND operation on the received signals. The plurality of inverters IV(M/2)+1 to IV(M) can receive and invert the outputs of the plurality of NAND gates ND(M/2)+1 to ND(M) and output the decoded signals ‘msb<M/2:M−1>’.

The operation of the mat selection decoding unit 210 shown in FIG. 7 will be described below.

In the multi test mode, the multi test active write signal ‘tm_multi_act_wt’ is, e.g., at a high level. Therefore, the (M+1)-th inverter IV(M+1) outputs a low-level signal, and the (M+1)-th NAND gate ND(M+1) outputs a high-level signal. Therefore, the up mat decoder 212-2-1 outputs the pre-decoded signals ‘pmsb<0:M/2−1>’ as the decoded signals ‘msb<0:M/2−1>’. In addition, the first NOR gate NOR1 outputs a low-level signal, and the second inverter IV2 outputs a high-level signal. Therefore, the down mat decoder 212-2-2 outputs the pre-decoded signals ‘pmsb<0:M/2−1>’ as decoded signals ‘msb<M/2:M−1>’. Therefore, when the multi test active write signal ‘tm_multi_act_wt’ is at a high level, both the down mat decoder 212-2-2 and the up mat decoder 212-2-1 output the pre-decoded signals ‘pmsb<0:M/2−1>’ as the decoded signals ‘msb<0:M−1>’.

When the (M+1)-th inverter IV(M+1) outputs a high-level signal and the up/down information address signal ‘Xadd<p>’ is at a high level, the (M+1)-th NAND gate ND(M+1) outputs a low-level signal. When the (M+1)-th inverter IV(M+1) outputs a high-level signal and the up/down information address signal ‘Xadd<p>’ is at a low level, the (M+1)-th NAND gate ND(M+1) outputs a high-level signal. When the up/down information address signal ‘Xadd<p>’ is at the high level, the (M+1)-th NAND gate ND(M+1) outputs the low-level signal. Therefore, the up mat decoder 212-2-1 outputs the decoded signals ‘msb<0:M/2−1>’ at a low level, regardless of the pre-decoded signals ‘pmsb<0:M/2−1>’.

When the up/down information address signal ‘Xadd<p>’ is at the low level, the (M+1)-th NAND gate ND(M+1) outputs the high-level signal. Therefore, the up mat decoder 212-2-1 outputs the pre-decoded signals ‘pmsb<0:M/2−1>’ as the decoded signals ‘msb<0:M/2−1>’.

In a normal mode, when the multi test active write signal ‘tm_multi_act_wt’ is at a low level and the up/down information address signal ‘Xadd<p>’ is at a low level, the first NOR gate NOR1 outputs a high-level signal, and the (M+2)-th inverter IV(M+2) outputs a low-level signal. Therefore, the down mat decoder 212-2-2 outputs the decoded signals msb<M/2:M−1>at a low level, regardless of the pre-decoded signals pmsb<0:M/2−1>. When the multi test active write signal ‘tm_multi_act_wt’ is at a low level and the up/down information address signal ‘Xadd<p>’ is at a high level, the first NOR gate NOR1 outputs a low-level signal, and the (M+2)-th inverter IV(M+2) outputs a high-level signal. Therefore, the down mat decoder 212-2-2 outputs the pre-decoded signals ‘pmsb<0:M/2−1>’ as the decoded signals ‘msb<M/2:M−1>’.

That is, when the up/down information address signal ‘Xadd<p>’ is at the low level, the up mat decoder 212-2-1 outputs the pre-decoded signals ‘pmsb<0:M/2−1>’ as the decoded signals ‘msb<0:M/2−1>’, and the down mat decoder 212-2-2 outputs the decoded signals ‘msb<M/2:M−1>’ at a low level. Further, when the up/down information address signal ‘Xadd<p>’ is at the high level, the up mat decoder 212-2-1 outputs the decoded signals ‘msb<0:M/2−1>’ at a low level, and the down mat decoder 212-2-2 outputs the pre-decoded signals ‘pmsb<0:M/2−1>’ as the decoded signals ‘msb<M/2:M−1>’.

Therefore, when multi test mode active write signal ‘tm_multi_act_wt’ is at a high level, the up mat decoder 212-2 and the down mat decoder 212-2 output the pre-decoded signals ‘pmsb<0:M/2−1>’ as the decoded signals ‘msb<0:M−1>’. On the other hand, when the multi test mode active write signal ‘tm_multi_act_wt’ is at the low level, signals for enabling mats corresponding to the mat information address signals ‘Xadd<k:P>’ and the up/down information address signal ‘Xadd<p>’ are output as the decoded signals ‘msb<0:M−1>’.

Referring again to FIG>4, the mat control section 300 can receive the up mat input/output switch control signal ‘iosw_en_up’, the down mat input/output switch control signal ‘iosw_en_dn’, and the multi mat selection signals ‘msb<0:M−1>’, and enable the word lines, the sense amplifiers, and the input/output switches corresponding to the signals.

The mat control section 300 can receive the multi mat selection signals ‘msb<0:M−1>’ and the up mat input/output switch control signal ‘iosw_en_up’, and output signals for enabling the up mats. In addition, the mat control section 300 can receive the multi mat selection signals ‘msb<0:M−1>’ and the down mat input/output switch control signal ‘iosw_en_dn’ and output signals for enabling the down mats.

The mat control section 300 can include an up mat control unit 310 and a down mat control unit 320. The up mat control unit 310 can receive the multi mat selection signals ‘msb<0:M−1>’ and the up mat input/output switch control signal ‘iosw_en_up’ and output signals for enabling the up mats. The down mat control unit 320 receives the multi mat selection signals ‘msb<0:M−1>’ and the down mat input/output switch control signal ‘iosw_en_dn’, and output signals for enabling the down mats.

For example, the up mat control unit 310 and the down mat control unit 320 output word line enable signals ‘WL_en<0:M−1>’, sense amplifier enable signals ‘SA_en<0:M−1>’, and up mat input/output switch signals ‘iosw<0:M−1>’ corresponding to their mats.

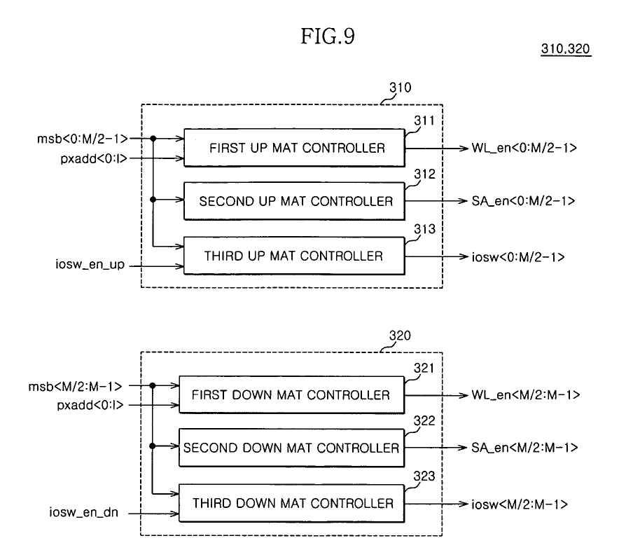

Referring to FIG. 9, the up mat control unit 310 can include first to third up mat controllers 311 to 313. The first up mat controller 311 can be configured to receive the multi mat selection signals ‘msb<0:M/2−1>’ and a predetermined address signal ‘pxadd<0:l>’ and output the word line enable signals ‘WL_en<0:M/2−1>’. The second up mat controller 312 can receive the multi mat selection signals ‘msb<0:M/2−1>’ and output the sense amplifier enable signals ‘SA_en<0:M/2−1>’. The third up mat controller 313 can receive the multi mat selection signals ‘msb<0:M/2−1>’ and the up mat input/output switch control signal ‘iosw_en_up’, and output the input/output switch signals ‘iosw<0:M/2−1>’.

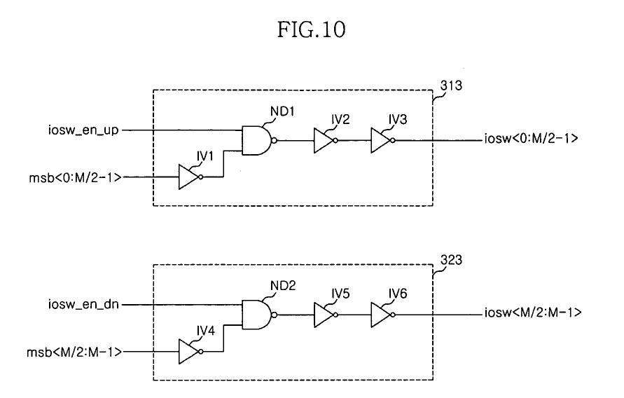

The up mat control unit 310 will be described in more detail with reference to FIG. 10. As can be seen, the third up mat controller 313 can include a first NAND gate ND1 and first to third inverters IV1 to IV3, and output the input/output switch signals ‘iosw<0:M/2−1>’. The first inverter IV1 can receive and invert the multi mat selection signals ‘msb<0:M/2−1>’. The first NAND gate ND1 can receive the up mat input/output switch control signal ‘iosw-en-up’ and the output of the first inverter IV1, and perform a NAND operation on the received signals. The second inverter IV2 can invert the output of the first NAND gate ND1. The third inverter IV3 can receive and invert the output of the second inverter IV2, and output the input/output switch signals ‘iosw<0:M/2−1>’ corresponding to the up mats.

The first up mat controller 311 and the second up mat controller 312 can be implemented in the same manner as in a conventional circuit. As such, and a detailed description thereof will be omitted.

When the up mat input/output switch control signal ‘iosw_en_up’ is at a low level, the input/output switch signals ‘iosw<0:M/2−1>’ corresponding to the up mats are fixed to a high level, regardless of the multi mat selection signals ‘msb<0:M/2-1>’. In addition, when the up mat input/output switch control signal ‘iosw_en_up’ is at a high level and the multi mat selection signals ‘msb<0:M/2−1>’ are at a high level, the input/output switch signals ‘iosw<0:M/2−1>’ corresponding to the up mats transitions to a high level. When the multi mat selection signals ‘msb<0:M/2−1>’ are at a low level, the input/output switch signals ‘iosw<0:M/2−1>’ corresponding to the up mats transitions to a low level.

Referring to FIG. 9, the down mat control unit 320 can include first to third down mat controllers 321 to 323. The first down mat controller 321 can receive the multi mat selection signals ‘msb<M/2:M−1>’ and a predetermined address signal ‘pxadd<0:l>’, and output the word line enable signals ‘WL_en<M/2:M−1>’. The second down mat controller 322 can receive the multi mat selection signals ‘msb<M/2:M−1>’ and output the sense amplifier enable signals ‘SA_en<M/2:M−1>’. The third down mat controller 323 can receive the multi mat selection signals ‘msb<M/2:M−1>’ and the down mat input/output switch control signal ‘iosw_en_dn’, and output the input/output switch signals ‘iosw<M/2:M−1>’.

The above will be described in more detail with reference to FIG. 10. The third down mat controller 323 can include a second NAND gate ND2, and fourth to sixth inverters IV4 and IV6 and output the input/output switch signals ‘iosw<M/2:M−1>’. The fourth inverter IV4 can receive and invert the multi mat selection signals ‘msb<M/2:M−1>’. The second NAND gate ND2 can receive the down mat input/output switch control signal ‘iosw_en_dn’ and the output of the fourth inverter IV4, and perform a NAND operation on the received signals. The fifth inverter IV5 can receive and invert the output of the second NAND gate ND2. The sixth inverter IV6 can receive and invert the output of the fifth inverter IV5, and output the input/output switch signals ‘iosw<M/2:M−1>’ corresponding to the down mats.

Similar to the third up mat controller 313, the third down mat controller 323 can be configured to activate or deactivate input/output switch signals ‘iosw<M/2:M−1>’ corresponding to the down mats according to the down mat input/output switch control signal ‘iosw_en_dn’ and the multi mat selection signals ‘msb<M/2:M−1>’.

The first down mat controller 321 and the second down mat controller 322 can be implemented in a manner similar to a conventional circuit. As such, a detailed description thereof will be omitted.

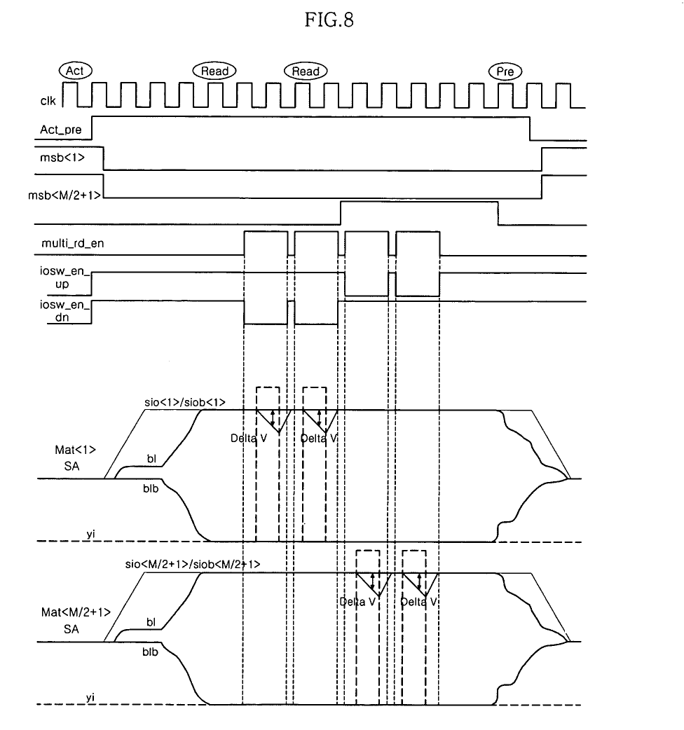

The operation of the semiconductor integrated circuit 1 configured as shown in FIGS. 4 to 7 will be described below with reference to the timing diagram shown in FIG. 8.

In the multi test mode, when the active signal ‘act_pre’ is enabled and the multi test mode active write signal ‘tm_multi_act_wt’ is enabled, then an activation operation will begin. The mat selection decoding unit 210 will then output the pre-decoded signals ‘pmsb<0:M/2−1>’ as the decoded signals ‘msb<0:M−1>’ regardless of the up/down information address signal ‘Xadd<p>’. For example, it is assumed that addresses for enabling a first mat corresponding to the up mat and a (M/2+1)-th mat corresponding to the down mat are received. A mat selection signal ‘msb<1>’ for enabling the first mat, which is one of the plurality of up mats corresponding to the pre-decoded signal ‘pmsb<0:M/2−1>’, is enabled, and a mat selection signal ‘msb<M/2+1>’ for enabling the (M/2+1)-th mat, which is one of a plurality of down mats corresponding to the pre-decoded signal ‘pmsb<0:M/2−1>’, is enabled. Since two mat selection signals ‘msb<1>’ and ‘msb<M/2+1>’ are enabled, the word lines in the two mats are enabled, and the active operation is performed. Therefore, it is possible to shorten a test time.

Thereafter, in the read operation mode, data that is loaded on cells corresponding to the word lines in the first mat can be read. When the column pulse enable signal ‘pre_yi_pulse_en’ is enabled, the multi read signal ‘multi_rd_en’ is enabled according to the column pulse enable signal ‘pre_yi_pulse_en’ (the multi read signal generating unit 110 shown in FIG. 5 outputs the multi read signal ‘multi_rd_en’ that is enabled with a larger width than that of the column pulse enable signal ‘pre_yi_pulse en’). Therefore, the input/output switch control signal generating unit 120 receives the enabled multi read signal ‘multi_rd_en’, and enables the up mat input/output switch control signal ‘iosw_en_up’ corresponding to the first mat according to the up/down information address signal ‘Xadd<p>’. In addition, the input/output switch control signal generating unit 120 receives the multi read signal ‘multi_rd_en’, and disables the down mat input/output switch control signal ‘iosw_en_dn’ corresponding to the (M/2+1)-th mat. Therefore, the up mat control unit 310 receives the enabled up mat input/output switch control signal ‘iosw_en_up’ and outputs an enabled input/output switch signal.

The down mat control unit 320 receives the down mat input/output switch control signal ‘iosw_en_dn’, which is a low-level pulse, and outputs a disabled input/output switch signal. Therefore, the input/output switch is turned on, and data that is loaded on the cells corresponding to the word lines in the first mat is read. Then, the read data is transmitted in the order of the local input/output line, the input/output sense amplifier, and a data pad. Meanwhile, the transmission of data that is loaded on cells corresponding to the word lines in the (M/2+1)-th mat is interrupted since the input/output switch is turned off, and the data is not loaded to the local input/output lines.

After the read operation of the data loaded on the cells corresponding to the word lines in the first mat, an operation of reading data that is loaded on the cells corresponding to the word lines in the (M/2+1)-th mat is performed. The read operation is performed by the same method as that for the first mat.

As a result, in the active mode, the first mat and the (M/2+1)-th mat are simultaneously activated. In the read operation mode, data in the first mat may be read earlier than data in the (M/2+1)-th mat. Therefore, the time required for the active operation is shortened, and the time required for the read operation of data from the first mat is different from the time required for the read operation of data from the (M/2+1)-th mat.

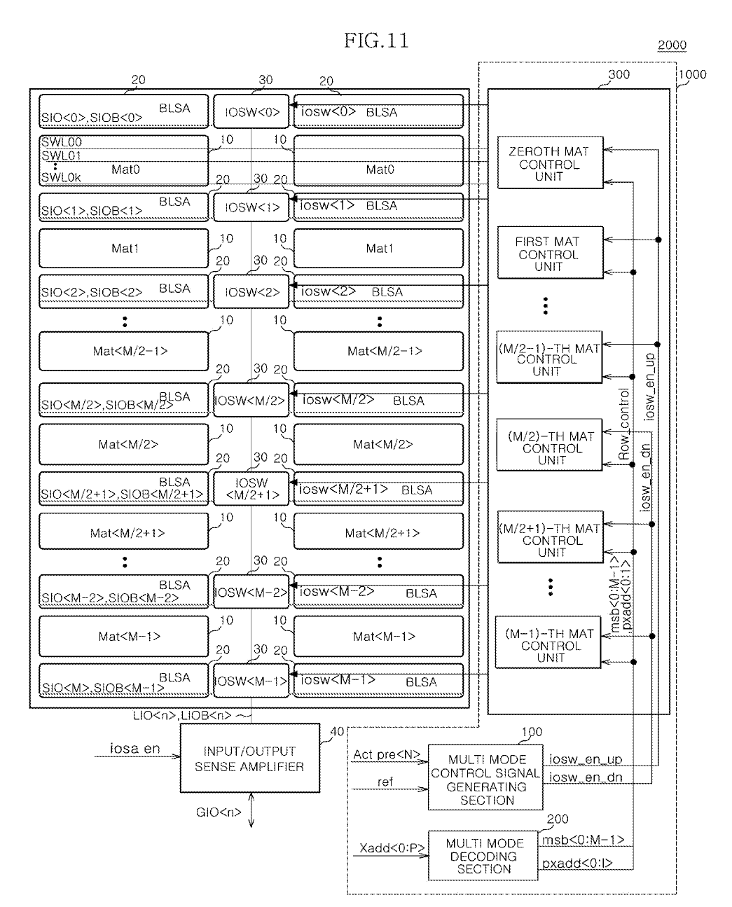

A semiconductor integrated circuit 2000 according to another embodiment is shown in FIG. 11 and can include a plurality of mats 10, a plurality of bit line sense amplifier array blocks 20, a plurality of input/output switching units 30, a multi-mode control signal generating section 100, a multi-mode decoding section 200, a mat control section 300, and an input/output sense amplifier 40.

The multi-mode control signal generating section 100, the multi-mode decoding section 200, and the mat control section 300 can have the same structures as those in the above-described embodiment. Therefore, a semiconductor integrated circuit 1000 according to this embodiment can output the input/output switch signals ‘iosw<0:M−1>’, the sense amplifier enable signals ‘SA_en<0:M−1>’, and the word line enable signals ‘WL_en<0:M−1>’. The input/output switching units 30 can be turned on according to the input/output switch signals ‘iosw<0:M−1>’. The word lines in the mats can be activated according to the word line enable signals ‘WL_en<0:M−1>’. The bit line sense amplifiers 20 can be activated according to the sense amplifier enable signals ‘SA_en<0:M−1>’.

The semiconductor integrated circuit according to this embodiment can simultaneously activate two mats during the active mode of the test mode, thereby shortening the test time, and sequentially read the two mats one by one only after the active operation. For example, during a long RAS test, the semiconductor integrated circuit can activate the word lines for a long time, and then perform a test operation of reading data loaded on the cells. In this case, the semiconductor integrated circuit can simultaneously activate the word lines in a plurality of mats, and sequentially perform the read operation on the plurality of mats one by one during the read operation mode. Since the time required for the read operation is shorter than the time required to activate the word line, it is possible to shorten the test time by half when activating two mats at the same time.

In the above-described embodiment, two mats are simultaneously activated during the test mode, but it will be understood that two or more mats can be simultaneously activated during the test mode.

That is, when two mats are simultaneously activated, the test time can be reduced by half, and when four mats are simultaneously activated, the test time can be reduced to a quarter of the time required to activate four mats individually.

The semiconductor integrated circuit according to the above-described embodiments can simultaneously activate a plurality of mats in order to reduce the test time and prevent data collision. As a result, it is possible to significantly reduce the test time and manufacturing costs, and improve mass production efficiency.

While certain embodiments have been described above, it will be understood that the embodiments described are by way of example only. Accordingly, the systems and methods described herein should not be limited based on the described embodiments. Rather, the systems and methods described herein should only be limited in light of the claims that follow when taken in conjunction with the above description and accompanying drawings.

What is claimed is:

1. A semiconductor integrated circuit comprising:
a multi-mode control signal generating section configured to enable one of up and down mat input/output switch control signals for controlling input/output switches in up/down mats according to up/down information addresses during a read operation of a multi test mode;
a multi-mode decoding section configured to simultaneously activates multi mat selection signals corresponding to one of the up mats and one of the down mats according to row addresses, during an active operation of the multi test mode; and
a mat control section configured to receive the up and down mat input/output switch control signals and the multi mat selection signals and enables word lines and input/output switches in the up and down mats corresponding to the signals.

2. The semiconductor integrated circuit of claim 1, wherein the multi-mode decoding section is further configured to receive and decode the row addresses according to multi test mode active write signals and output the multi mat selection signals and PX address signals.

3. The semiconductor integrated circuit of claim 1, wherein the mat control section includes:
an up mat control unit configured to enable the input/output switches in one of the up mats corresponding to the multi mat selection signals and the PX address signals according to the up mat input/output switch control signals; and
a down mat control unit configured to receive the multi mat selection signals and the PX address signals according to the down mat input/output switch control signals, and enable the input/output switches in one of the down mats.

4. The semiconductor integrated circuit of claim 1, wherein the multi-mode control signal generating section includes:
a multi read signal generating unit configured to receive the multi test mode signals and column pulse enable signals and output multi read signals; and
an input/output switch control signal generating unit configured to receive the multi read signals according to the up/down information address signals and the active signals, and output the up/down mat input/output switch control signals.

5. The semiconductor integrated circuit of claim 4, wherein the multi read signal generating unit is further configured to output an enabled multi read signal when the multi test signal and the column pulse enable signal are enabled.

6. The semiconductor integrated circuit of claim 4, wherein the input/output switch control signal generating unit includes:
an active driver configured to receive the active signal and a refresh signal and generate an output based thereon;
a multi test controller configured to receive the up/down information address and the multi read signal and generate an output based thereon; and
an output unit that configured to receive the outputs of the active driver and the multi test controller, and output the up mat input/output switch control signal and the down mat input/output switch control signal based thereon.

7. The semiconductor integrated circuit of claim 2, wherein the multi-mode decoding section includes:
a mat selection decoding unit configured to receive and decode a mat information address of the row addresses according to the multi test mode active write signal, and output the multi mat selection signal; and
a PX decoding unit configured to receive and decode the other addresses of the row addresses except for the mat information address according to the active signal, and output the PX address signals.

8. The semiconductor integrated circuit of claim 7, wherein the mat selection decoding unit includes:
a mat block pre-decoder configured to pre-decode the other addresses of the mat information addresses except for the up/down information address and output pre-decoded signals; and
a main decoder configured to receive and decode the pre-decoded signals according to the multi test mode active write signal and the up/down information address.

9. The semiconductor integrated circuit of claim 8, wherein the main decoder includes:
a mat control unit configured to receive the multi test mode active write signal and the up/down information address and output an up mat control signal and a down mat control signal; and
a decoder configured to receive the pre-decoded signal, the up mat control signal, and the down mat control signal and output a decoded signal.

10. The semiconductor integrated circuit of claim 9, wherein the mat control unit includes:
an up mat controller configured to output an enabled up mat control signal when the up mat is selected in the multi test mode; and
a down mat controller configured to output an enabled down mat control signal when the down mat is selected in the multi test mode.

11. The semiconductor integrated circuit of claim 9, wherein the decoder includes:
an up mat decoder configured to receive the up mat control signal and the pre-decoded signal and output up mat selection signals; and
a down mat decoder configured to receive the down mat control signal and the pre-decoded signal and output down mat selection signals.

12. The semiconductor integrated circuit of claim 11, wherein the up mat decoder is configured to output the pre-decoded signal belonging to the up mat as a decoded signal when the up mat control signal is enabled.

13. The semiconductor integrated circuit of claim 11, wherein the down mat decoder is configured to output the pre-decoded signal belonging to the down mat as a decoded signal when the down mat control signal is enabled.

14. The semiconductor integrated circuit of claim 12, wherein the up mat decoder includes:
a plurality of NAND gates each of which is configured to receive the pre-decoded signal belonging to the up mat among the pre-decoded signals and the up mat control signal, and generate an output based thereon; and
a plurality of inverters configured to receive and invert the outputs of the plurality of NAND gates and output the decoded signals.

15. The semiconductor integrated circuit of claim 13, wherein the down mat decoder includes:
a plurality of NAND gates each of which is configured to receive the pre-decoded signal belonging to the down mat among the pre-decoded signals and the down mat control signal, and generate an output based thereon; and
a plurality of inverters configured to receive and invert the outputs of the plurality of NAND gates and output the decoded signals.

16. A multi test method of a semiconductor integrated circuit, the method comprising:
activating one of up mats and one of down mats to perform an active operation when a multi test is performed;
activating an up mat input/output switch control signal and deactivating a down mat input/output switch control signal according to up/down information addresses;
reading data from one of the up mats according to the activated up mat input/output switch control signal;
deactivating the up mat input/output switch control signal and activating the down mat input/output switch control signal according to the up/down information addresses; and
reading data from one of the down mats according to the activated down mat input/output switch control signal.

17. The multi test method of claim 16, wherein the activating of one of the up mats and one of the down mats includes:
receiving and pre-decoding a row address and outputting a pre-decoded signal;
outputting an enabled up mat control signal and an enabled down mat control signal according to a multi test mode active write signal and the up/down information address; and
receiving the enabled up mat control signal and the enabled down mat control signal, and outputting the pre-decoded signal as a decoded signal to each of the up mats and each of the down mats.

18. The multi test method of claim 16, wherein the activating of the up mat input/output switch control signal and the deactivating of the down mat input/output switch control signal include:
when a multi test mode signal is enabled, receiving an enabled column pulse enable signal, and outputting an enabled multi read signal; and
receiving the enabled multi read signal, and activating the up mat input/output switch control signal and deactivating the down mat input/output switch control signal according to the up/down information address.

19. The multi test method of claim 16, wherein the reading of data from one of the up mats includes turning on an up mat input/output switch according to the activated up mat input/output switch control signal to output up mat data to a local input/output line.

20. The multi test method of claim 16, wherein the deactivating of the up mat input/output switch control signal and the activating of the down mat input/output switch control signal include:
when a multi test mode signal is enabled, receiving an enabled column pulse enable signal, and outputting an enabled multi read signal; and
receiving the enabled multi read signal, and deactivating the up mat input/output switch control signal and activating the down mat input/output switch control signal according to the up/down information address.

21. The multi test method of claim 16, wherein the reading of data from one of the down mats includes turning on a down mat input/output switch according to the activated down mat input/output switch control signal to output down mat data to a local input/output line.
